(19) United States
(12) Patent Application Publication
(10) Pub. No.: US 2008/0233284 A1
(43) Pub. Date: Sep. 25, 2008

(54) Bottom-Up Electrospinning Devices, and Nanofibers Prepared by Using the Same

(76) Inventors: Hak-Yong Kim, Chonrabuk-do (KR); Jong-Cheol Park, Seoul (KR)

Correspondence Address: BIRCH STEWART KOLASCH & BIRCH, PO BOX 747, FALLS CHURCH, VA, 22040-0747, US

(21) Appl. No.: 10/592,314

(22) PCT Filed: Apr. 29, 2004
(86) PCT No.: PCT/KR2004/000985

§ 371 Date: Sep. 11, 2006

(30) Foreign Application Priority Data
Mar. 23, 2004 (KR) 10-2004-0019543

(51) Int. Cl. C23C 16/00; D01F 9/12; B05D 1/16

(52) U.S. Cl. 427/248.1; 423/447.3; 427/462; 977/961

(57) ABSTRACT

A conventional electrospinning devices is problematic in that it is unable to mass-produce a nanofiber web and the quality of a produced nanofiber web is poor. To solve the above problem, the present invention provides a bottom-up electrospinning devices, wherein [I] the outlets of nozzles 5 installed on a nozzle block 4 are formed in an upper direction; [II] a collector 7 is located on the top part of the nozzle block 4; and [III] overflow removing nozzles 4a and air feeding nozzles 4b are sequentially installed around nozzle outlets.

### TECHNICAL FIELD

The present invention relates to a bottom-up electrospinning devices which is capable of mass-producing fibers having a nano level thickness (hereinafter, nanofiber), and a nanofiber produced using the same.

Products such as nonwoven fabrics, membranes, braids, etc. composed of nanofibers are widely used for daily necessaries and in agricultural, apparel and industrial applications, etc. Concretely, they are utilized in a wide variety of fields, including artificial leathers, artificial suede, sanitary pads, clothes, diapers, packaging materials, miscellaneous goods materials, a variety of filter materials, medical materials such as gene transfer elements, military materials such as bullet-proof vests, and the like.

### BACKGROUND ART

A conventional electrospinning devices and a method for producing nanofibers using the same disclosed in U.S. Pat. No. 4,044,404 are described as follows.

The conventional electrospinning devices comprises: a spinning liquid main tank for storing a spinning liquid; a metering pump for quantitatively feeding the spinning liquid; a nozzle block with a plurality of nozzles arranged for discharging the spinning liquid; a collector located on the lower end of the nozzles and for collecting spun fibers; and a voltage generator for generating a voltage.

Namely, the conventional electrospinning devices is a bottom-up electrospinning devices in which a collector is located at the lower end of the nozzles.

The conventional method for producing nanofibers using the bottom-up electrospinning devices will be described, in more detail. A spinning liquid in the spinning liquid main tank continues to be quantitatively fed into the plurality of nozzles with a high voltage through the metering pump.

Continually, the spinning liquid fed into the nozzles is spun and collected on the collector with a high voltage through the nozzles to form a single fiber web.

Continually, the single fiber web is embossed or needle-punched to prepare a nonwoven fabric.

The aforementioned conventional bottom-up electrospinning devices and the method for producing nanofibers using the same is problematic in that a spinning liquid is continuously fed to nozzles with a high voltage applied thereto to thereby greatly deteriorate the electric force effect.

Meanwhile, a conventional horizontal electrospinning devices with nozzles and a collector arranged in a horizontal direction has a drawback that it is very difficult to arrange a plurality of nozzles for spinning. That is, it is difficult to arrange the nozzles located on the uppermost line, the nozzles located on the lowermost line and the collector at the same spinning distance (tip-to-collector distance) in order to raise a nozzle plate including nozzles and a spinning liquid in a direction horizontal to the collector, thus there is no alternative but to arrange a limited number of nozzles.

Generally, electrospinning is carried out at a very low throughput rate of 10⁻² to 10⁻³ g/min per hole. Thus, for mass production needed in commercialization, a plurality of nozzles should be arranged in a narrow space.

However, in the conventional electrospinning devices, it is impossible to arrange a limited number of nozzles in a predetermined space as explained above, thus making mass production needed for commercialization difficult.

The conventional electrospinning devices has a problem that electrospinning is mostly done at about one hole level and this disables mass production to make commercialization difficult.

Further, the conventional horizontal electrospinning devices has another problem that there occurs a phenomenon (hereinafter, referred to as ‘droplet’) that a polymer liquid aggregate not spun through the nozzles is adhered to a collector plate, thereby deteriorating the quality of the product.

To overcome the aforementioned problems, there was proposed an bottom-up electrospinning devices in which a collector is located on the top part of a nozzle plate.

The conventional bottom-up electrospinning devices is advantageous for the mass production of nanofibers since thousands or ten thousands of nozzles are able to be easily arranged in a narrow nozzle block. But, when electrospun nanofibers are collected on a collector, the surface area becomes smaller because the gap between the nozzles is small. Thus, even if the collector or nozzle block is moved to the left or right, the accumulation density of the nanofiber becomes uneven.

As a result, the weight density of a produced nonwoven fabric becomes uneven, or the collection density of the nanofibers to be coated on a base material becomes uneven.

### BRIEF DESCRIPTION OF THE DRAWINGS

These and other features, aspects, and advantages of preferred embodiments of the present invention will be more fully described in the following detailed description, taken accompanying drawings. In the drawings:

FIG. 1 is a schematic view of a process for producing a nanofiber web using an bottom-up electrospinning devices in accordance with the present invention;

FIG. 2 is a schematic view of a process of coating nanofibers on a coating material using the bottom-up electrospinning devices in accordance with the present invention;

FIG. 3 is a schematic view of a process for producing a hybrid type nanofiber web using the bottom-up electrospinning devices in accordance with the present invention;

FIG. 4 is a pattern diagram of a nozzle block 4;

FIG. 5 is an enlarged pattern diagram of a nozzle outlet portion through which nanofibers are electrospun;

FIGS. 6 and 8 are pattern diagrams showing the sides of a nozzle 5;

FIGS. 7 and 9 are plane views exemplifying the nozzle 5;

FIG. 10(a) is a cross sectional view of a spinning liquid dropping device 3 in the present invention;

FIG. 10(b) is a perspective view of the spinning liquid dropping device 3 in the present invention;

FIG. 11 is an electron micrograph of a paper/polypropylene nonwoven fabric before coating nanofiber in Example 1; and

FIG. 12 is an electron micrograph of a paper/polypropylene nonwoven fabric with a nylon 6 nanofiber coated thereto in Example 1.

### REFERENCE NUMERALS FOR MAIN PARTS IN THE DRAWINGS

| | | |
|---|---|---|
| 1: spinning liquid main tank | 2: metering pump | |
| 3: spinning liquid dropping device | | |
| 3a: filter of spinning liquid dropping device | | |
| 3b: gas inlet pipe | 3c: spinning liquid induction pipe | |
| 3d: spinning liquid discharge pipe | 4: nozzle block | |
| 4a: overflow removing nozzle | 4b: air feeding nozzle | |
| 4c: air feeding nozzle supporting plate (nonconductive material) | | |
| 4d: air storage plate | 4e: overflow removing nozzle supporting plate | |
| 4f: nozzle plate | 4g: overflowing liquid temporary storage plate | |
| 4h: spinning liquid feed plate | 4i conductive plate | |
| 4j: heating plate | 5: nozzle | |
| 6: nanofiber | 7: collector (conveyer belt) | |
| 8a, 8b: collector supporting roller | 9: voltage generator | |
| 10: nozzle block bilateral reciprocating device | | |
| 11a: motor for stirrer | 11b: nonconductive insulating rod | |
| 11c: stirrer | 12: spinning liquid discharge device | |
| 13: feed pipe | 14: web supporting roller | 15: web |
| 16: web takeup roller | 17: coating material feed roller | |
| θ: nozzle outlet angle | L: nozzle length | Di: nozzle inner diameter |
| Do: nozzle outer diameter | h: distance from upper tip of nozzle to upper | |
| | tip of air feeding nozzle | |

### DISCLOSURE OF THE INVENTION

The present invention provides an electrospinning devices which is capable of mass production of nanofiber, acquiring a high productivity per unit time by arrange a plurality of nozzles in a narrow area, make the accumulation density of nanofibers even by increasing the dispersion surface area of nanofibers electrospun to a collector, and producing a nanofiber of high quality and a nonwoven fabric thereof by preventing a droplet phenomenon.

For this purpose, the present invention proposes a bottom-up electrospinning devices in which a nozzle block with overflow removing nozzles and air feeding nozzles sequentially installed around nozzle outlets is located at the lower end of a collector.

To achieve the above objects, there is provided a bottom-up electrospinning devices in accordance with the present invention, wherein: [I] the outlets of nozzles installed on a nozzle block 4 are formed in an upper direction; [II] a collector is located on the top part of the nozzle block 4; and [III] overflow removing nozzles 4a and air feeding nozzles 4b are sequentially installed around the outlets of the nozzles 5.

Hereinafter, the present invention will be described in detail with reference to the accompanying drawings.

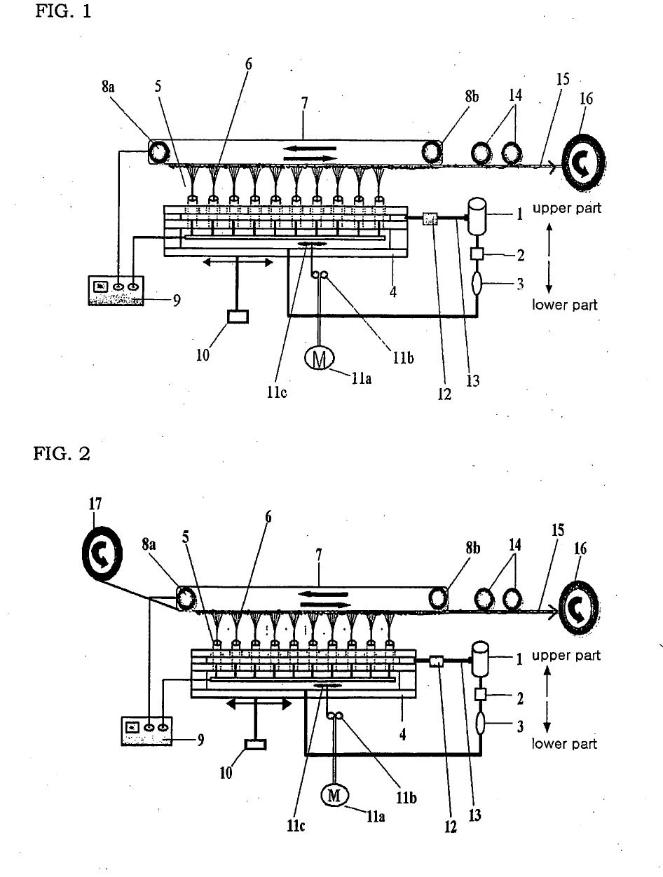

As shown in FIG. 1, a bottom-up electrospinning devices of the present invention includes: a spinning liquid main tank 1 for storing a spinning liquid; a metering pump 2 for quantitatively feeding the spinning liquid; a nozzle block 4 with nozzles 5 consisting of a plurality of pins combined in a block shape and for discharging the spinning liquid onto fibers; a collector 7 located above the nozzle block and for collecting single fibers being spun; a voltage generator 9 for generating a voltage; and a spinning liquid discharge device 12 connected to the uppermost part of the nozzle block.

In the present invention, the outlets of the nozzles 5 installed on the nozzle block 4 are formed in an upper direction, and the collector 7 is located above the nozzle block 4 to spin a spinning liquid in an upper direction.

As shown in FIG. 4, the nozzle block 4 includes: [I] a nozzle plate 4f with nozzles 5 arranged thereon and a spinning liquid feed plate 4h located on the lower end of the nozzle plate and for feeding a spinning liquid to the nozzles; [II] overflow removing nozzles 4a surrounding the nozzles 5, an overflowing liquid temporary storage plate 4g connected to the overflow removing nozzles and located right below the nozzle plate and overflow removing nozzle supporting plate 4e located right above the overflowing liquid temporary storage plate and supporting the overflow removing nozzles; [III] air feeding nozzles 4b surrounding the nozzles 5 and the overflow removing nozzles 4a, an air feeding nozzle supporting plate 4c located on the uppermost end of the nozzle block and for supporting the air feeding nozzles and an air storage plate 4d located right below the air feeding nozzle supporting plate and for feeding air to the air feeding nozzles; [IV] a conductive plate 4i having pins arranged thereon in the same way as the nozzles are and located below the nozzle plate; and [V] a heating plate 4j located right below the spinning liquid feed plate.

As shown in FIG. 4, overflow removing nozzles 4a for removing non-spun spinning liquids and air feeding nozzles 4b for feeding air to make the accumulation distribution of nanofibers wider are sequentially installed around the nozzles 5 electrospinning a spinning liquid on the collector, thereby forming a triple pipe shape.

As shown in FIGS. 6 to 8, the outlets of the nozzles 5 for electrospinning a spinning liquid on the collector are formed in more than one horn whose exit is enlarged.

At this time, the angle θ is 90 to 175°, more preferably 95 to 150°, for stably forming spinning liquid drops of the same shape in the outlets of the nozzles 5.

If the angle θ of the nozzle outlets is more than 175°, drops formed in the nozzle region become larger to increase the surface tension.

As a result, an even higher voltage is required to form nanofibers. And, as spinning gets started not at the drop center regions but at the periphery portions, the drop center regions are solidified to block the nozzles.

Meanwhile, if the angle θ of the nozzle outlets is less than 90°, the drops formed in the nozzle outlet regions are very small. Thus, if an electric field becomes instantaneously nonuniform or the feeding to the nozzle outlet regions becomes slightly nonuniform, this may lead to the abnormalcy of a drop shape to thereby disable fiber formation and occur a droplet phenomenon.

The present invention does not specifically limit the length of the nozzles L, L1 and L2.

However, it is preferred that the nozzle inner diameter Di is 0.01 to 5 mm and the nozzle outer-diameter Do is 0.01 to 5 mm.

If the nozzle inner diameter or nozzle outer diameter is less than 0.01 mm, the droplet phenomenon may occur frequently. If more than 5 mm, this may disable fiber formation.

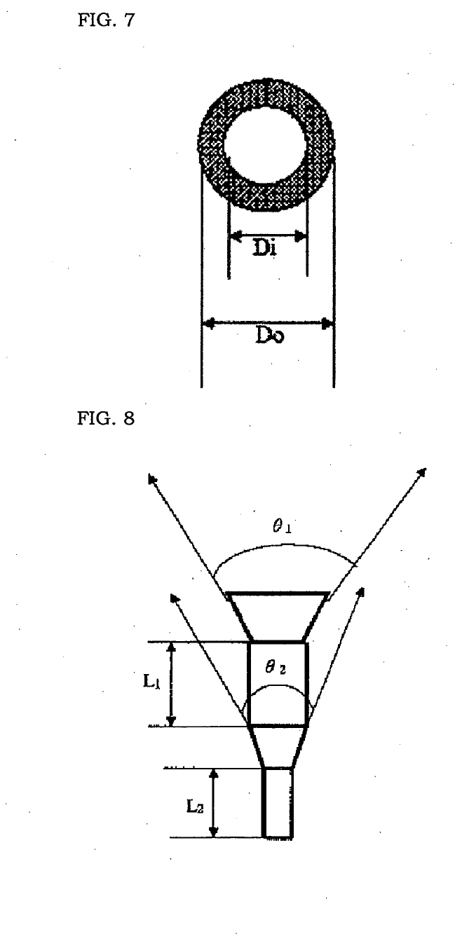

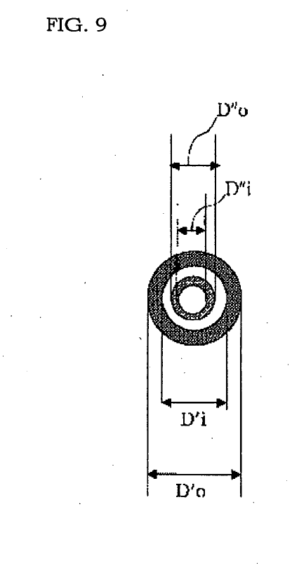

FIGS. 6 and 7 show the side and plane of a nozzle with one enlarged portion (angle) formed thereto. FIGS. 8 and 9 shows the side and plane of a nozzle with two enlarged portions (angle) formed thereto.

Namely, θ1 as shown in FIG. 8 is the angle of a first nozzle outlet at which a spinning liquid is spun, and θ2 is the angle of a second nozzle outlet at which the spinning liquid is fed.

A plurality of nozzles 5 in the nozzle block 4 are arranged on the nozzle plate 4f, and overflow removing nozzles 4a and air feeding nozzles 4b surrounding the nozzles 5 are sequentially installed on the outer parts of the nozzles 5.

The overflow removing nozzles 4a are installed for the purpose of preventing a droplet phenomenon which occurs in the event that an excessive quantity of a spinning liquid formed in the nozzle 5 outlets are not all made into fibers and recovering an overflowing spinning liquid, and play the role of gathering the spinning liquids not made into fibers at the nozzle outlets and feeding them to the overflowing liquid temporary storage plate 4g located right below the nozzle plate 4f.

Of course, the overflow removing nozzles 4a have a larger diameter than the nozzles 5 and preferably formed of an insulating material.

The overflowing liquid temporary storage plate 4g is made from an insulating material and plays the role of temporally storing the residual spinning liquid introduced through the overflow removing nozzles 4a and feeding it to the spinning liquid feed plate 4h.

An air storage plate 4d for feeding air is located on the upper end of the overflowing liquid temporary storage plate 4g and feeds air to the air feeding nozzles 4b surrounding the nozzles 5 and the overflow removing nozzles 4a.

Further, an air feeding nozzle supporting plate 4c is installed on the uppermost layer of the nozzle block 4 with the air feeding nozzles 4b arranged thereto. The supporting plate 4c is formed of a nonconductive material.

Since the air feeding nozzle supporting plate 4c is located on the nozzle block, the electric force applied between the collector 7 and the nozzles 5 is concentrated on the nozzles 5 alone, thereby allowing spinning to be smoothly done only on the nozzle 5 regions.

The distance h from the upper tips of the nozzles 5 to the upper tips of the air feeding nozzles 4b is 1 to 20 mm, and preferably 2 to 15 mm.

Namely, the height of the air feeding nozzles 4b is set 1 to 20 mm higher, and preferably 2 to 15 mm higher than the height of the nanofiber spinning nozzles 5.

If h is 0, that is, the air feeding nozzles 4b are located at the same height as the nozzles 5, this makes it difficult to form a jet stream effectively on the nozzle 5 portions, thereby decreasing the area in which nanofibers are attached on the collector 7.

Meanwhile, if h is more than 20 mm, an electric force becomes smaller due to a high voltage applied between the collector and the nozzles, thereby deteriorating the formability of nanofibers by electrospinning and making unstable the length or formation pattern of a jet stream.

Concretely, the stability of a jet-stream forming region in a Taylor cone is hindered.

Accordingly, it is difficult to carry out the spinning of nanofibers smoothly.

The air velocity in the air feeding nozzles 4b is 0.05 to 50 m/sec, and more preferably, 1 to 30 m/sec.

If the air velocity is less than 0.05 m/sec, the spreading property of nanofibers collected on the collector is poor and thus the collection area is not improved much. If the air velocity is more than 50 m/sec, the area in which nanofibers are concentrated on the collector is reduced because the air velocity is too high, to thereby reducing the uniformity of the collection of nanofibers.

The conductive plate 4i with pins arranged in the same manner as the arrangement of the nozzles is installed below the nozzle plate 4f, and the conductive plate 4i is connected to the voltage generator 9.

Further, the heating device (not shown) of direct heating type is installed right below the spinning liquid feed plate 4h.

The conductive plate 4i plays the role of applying a high voltage to the nozzles 5, and the spinning liquid feed plate 4h plays the role of storing a spinning liquid introduced from the spinning liquid dropping devices 3 to the spinning block 4. At this time, the spinning liquid feed plate 4h is preferably produced to occupy a minimum space so as to minimize the storage amount of the spinning liquid.

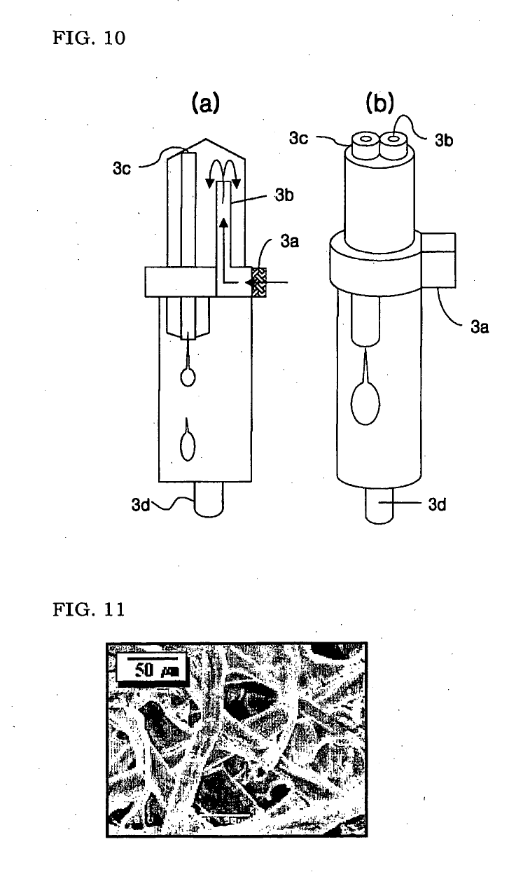

Meanwhile, the spinning liquid dropping device 3 of the present invention is overally designed to have a sealed cylindrical shape as shown in FIGS. 10(a) and 10(b) and plays the role of feeding the spinning liquid 4 in a drop shape continuously introduced from the spinning liquid main tank 1 to the nozzle block 4.

The spinning liquid dropping device 3 has an overally sealed cylindrical shape as shown in FIGS. 10(a) and 10(b).

FIG. 10(a) is a cross sectional view of the spinning liquid dropping device and FIG. 10(b) is a perspective view of the spinning liquid dropping device.

A spinning liquid induction pipe 3c for inducting a spinning liquid toward the nozzle block and a gas inlet pipe 3b are arranged side by side on the upper end of the spinning liquid dropping device 3.

At this time, it is preferred to form the spinning liquid induction pipe 3c slightly longer than the gas inlet pipe 3b.

Gas is introduced from the lower end of the gas inlet pipe, and the portion at which gas is firstly introduced is connected to a filter 3a. A spinning liquid discharge pipe 3d for inducting a dropped spinning liquid to the nozzle block 4 is formed on the lower end of the spinning liquid dropping device 3.

The middle part of the spinning liquid dropping device 3 is formed in a hollow shape so that the spinning liquid can be dropped at the tip of the spinning liquid induction pipe 3c.

The spinning liquid introduced to the spinning liquid dropping device 3 flows down along the spinning liquid induction pipe 3c and then dropped at the tip thereof, to thus block the flow of the spinning liquid more than once.

The principle of the dropping of the spinning liquid will be described concretely. If gas is introduced to the upper end of the sealed spinning liquid dropping device 3 along the filter 3a and the gas inlet pipe 3b, the pressure of the spinning liquid induction pipe 3c becomes naturally non-uniform by a gas eddy current or the like. Due to a pressure difference generated at this time, the spinning liquid is dropped.

In the present invention, as the gas to be introduced, can be used air, inert gases such as nitrogen, etc.

The entire nozzle block 4 of the present invention bilaterally reciprocates perpendicular to the traveling direction of nanofibers electrospun by a nozzle block bilateral reciprocating device 10 in order to make the distribution of electrospun nanofibers uniform.

Further, in the nozzle block 4, more concretely, in the spinning liquid main feed plate 4h, a stirrer 11c stirring the spinning liquid being stored in the nozzle block 4 is installed in order to prevent the spinning liquid from gelling.

The stirrer 11c is connected to a motor 11a by a nonconductive insulating rod 11b.

Once the stirrer 11c is installed in the nozzle block 4, it is possible to prevent the gelation of the spinning liquid in the nozzle block 4 effectively when electrospinning a liquid containing an inorganic metal or when electrospinning the spinning liquid dissolved with a mixed solvent for a long time.

Additionally, a spinning liquid discharge device 12 is connected to the uppermost part of the nozzle block 4 for forcedly feeding the spinning liquid excessively fed into the nozzle block to the spinning liquid main tank 1.

The spinning liquid discharge device 12 forcedly feeds the spinning liquid excessively fed into the nozzle block to the spinning liquid main tank 1 by a suction air or the like.

Further, a heating device (not shown) of direct heating type or indirect heating type is installed (attached) to the collector 7 of the present invention, and the collector 7 is fixed or continuously rotates.

The nozzles 5 located on the nozzle block 4 are arranged on a diagonal line or a straight line.

Next, a method for producing a nonwoven fabric using the bottom-up electrospinning devices of the present invention will be described.

Firstly, thermoplastic resin or thermosetting resin spinning liquid is metered by a metering pump 2 and quantitatively fed to a spinning liquid dropping device 3.

At this time, the thermoplastic resin or thermosetting resin used for preparing the spinning liquid includes polyester resin, acryl resin, phenol resin, epoxy rein, nylon resin, poly(glycolide/L-lactide). copolymer, poly(L-lactide) resin, polyvinyl alcohol resin, polyvinyl chloride resin, etc.

As the spinning liquid, either the resin melted solution or any other solution can be used.

The spinning liquid fed into the spinning liquid dropping device 3 is fed to the spinning liquid feed plate 4h of the nozzle block 4 of the invention, to which a high voltage is applied and a stirrer 11c is installed, in a discontinuous manner, i.e., in such a manner to block the flow of the spinning liquid more than once, while passing through the spinning liquid dropping device 3.

The spinning liquid dropping device 3 plays the role of blocking the flow of the spinning liquid so that electricity cannot flow in the spinning liquid main tank 1.

Continuously, the nozzle block 4 upwardly discharges the spinning liquid through bottom-up nozzles to the collector 7 at the top part where a high voltage is applied, thereby preparing a nonwoven fabric web.

The spinning liquid fed to the spinning liquid feed plate 4h is discharged to the collector 7 in the top part through the nozzles 5 to form fibers.

At this time, the nanofibers electrospun from the nozzles 5 are widely spread by the air blasted from the air feeding nozzles 4b and collected on the collector 7 to thus increase the collection area and make, the accumulation density even.

The excess spinning liquid not made into fibers at the nozzles 5 is gathered at the overflow removing nozzles 4a, passes through the overflowing liquid temporary storage plate 4g and moves again to the spinning liquid feed plate 4h.

Further, the spinning liquid excessively fed to the uppermost part of the nozzle block is forcedly fed to the spinning liquid main tank 1 by the spinning liquid discharge device 12.

At this time, to promote fiber formation by an electric force, a voltage of more than 1 kV, more preferably, more than 20 kV, generated from a voltage generator 6 is applied to the conductive plate 4i and collector 7 installed at the lower end of the nozzle block 4. It is more advantageous to use an endless belt as the collector 7 in view of productivity. It is preferable that the collector 7 reciprocates to the left and the right within a predetermined distance in order to make uniform the density of the nonwoven fabric.

The nonwoven fabric formed on the collector 7, passes through a web supporting roller 14 and is wound around a takeup roller 16, thereby finishing a nonwoven fabric producing process.

By the use of the above-described bottom-up nozzle block 4, the producing devices of the present invention is capable of making the accumulation density of nanofibers uniform with an increase of the collection area, improving the nonwoven fabric quality by effectively preventing a droplet phenomenon, and mass-producing nanofibers and nonwoven fabrics since the fiber formation effect becomes higher with an increase of electric force.

Moreover, the producing method of the present invention can freely change and adjust the width and thickness of a nonwoven fabric by arranging nozzles consisting of a plurality of pins in a block shape.

A nannofiber nonwoven fabric produced by the devices of the present invention is used for various purpose, including artificial leather, asanitary pad, a filter, medical materials such as an artificial vessel, a cold protection vest, a wiper for a semiconductor, a nonwoven fabric for a battery and the like.

The present invention comprises a method for coating nanofibers on a nonwoven fabric, a woven fabric, a knitted fabric, a film and membrane film (hereinafter, ‘coating materials’) by using the bottom-up electrospinning devices.

FIG. 2 is a schematic view of a process for coating nanofibers on a coating material using the bottom-up electrospinning devices in accordance with the present invention.

Concretely, while a coating material is continuously fed onto a collector 7 moving from a coating material feed roller 17, nanofibers are electrospun by the bottom-up electrospinning devices of the present invention on the coating material located on the collelctor 7, and then the coating material coated with nanofibers is wound by a takeup roller 16.

At this time, it is possible to coat nanofibers in a multilayer by electrospinning more than two kinds of spinning liquids on the coating material, respectively, by respective bottom-up electrospinning devices.

The coating thickness is properly adjustable according to a purpose.

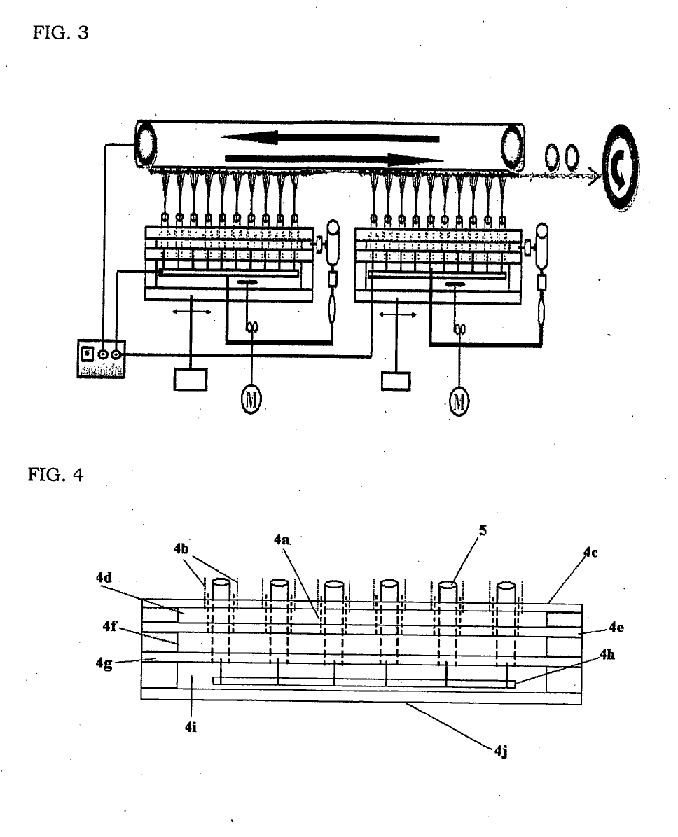

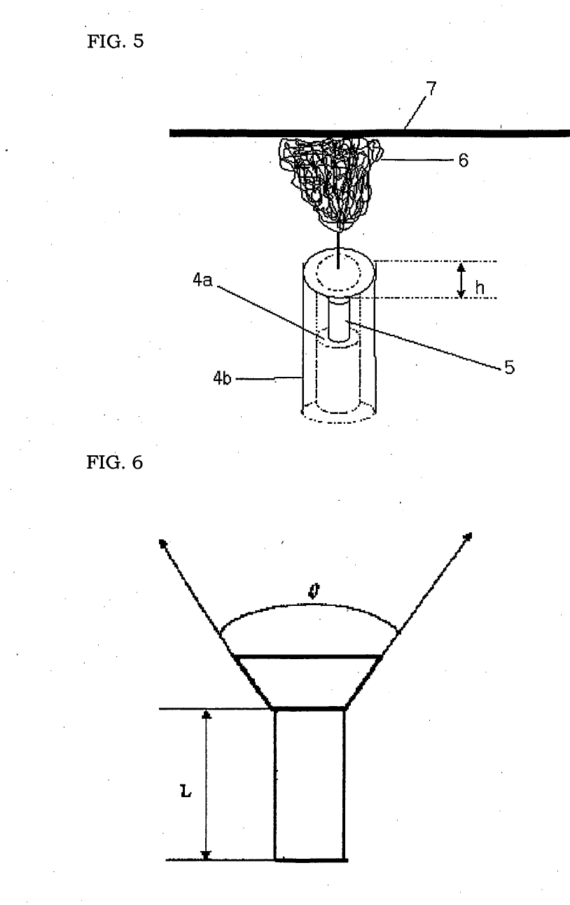

Further, as shown in FIG. 3, the present invention comprises a method for producing a hybrid type nanofiber web by consecutively arranging more than two kinds of bottom-up electrospinning devices side by side and then electrospinning more than two kinds of spinning liquids by respective bottom-up electrospinning devices and a method for manfacutirng a hybrid type nanofiber web by stacking more than two kinds of nanofiber webs electrospun respectively by the bottom-up electrospinning devices.

FIG. 3 is a schematic view of a process for producing a hybrid type nanofiber web using two bottom-up electrospinning devices arranged side by side, in which reference numerals for main parts of the drawings are omitted.

### Advantageous Effect

The present invention is able to make the accumulation density of nanofibers of a web to be produced because the collection area of nanofibers on a collector can be increased, and coat nanofibers on a base material at a uniform density.

Furthermore, the present invention enables an infinite nozzle arrangement by arranging a plurality of nozzles on a flat nozzle block plate upon electrospinning of nanofibers, and is capable of enhancing productivity per unit time with the improvement of fiber forming property.

As a result, the present invention is able to commercially produce a nanofiber web. Additionally, the present invention is able to effectively prevent a droplet phenomenon and mass-produce nanofibers of high quality.

### Best Mode for Carrying Out the Invention

Hereinafter, the present invention will now be described more concretely through the following examples.

However, the present invention is not limited thereto.

### EXAMPLE 1

Chips of nylon 6 having a relative viscosity of 3.2 (determined in a 96% sulfuric acid solution) were dissolved in formic acid to prepare a 25% spinning liquid. The spinning liquid had a viscosity of 1200 centipoises (cPs) measured by using Rheometer-DV, III, Brookfield Colo., USA, an electric conductivity of 350 mS/m measured by a conductivity meter, CM-40G, TOA electronics Co., Japan, and a surface tension of 58 mN/m measured by a tension meter (K10St, Kruss Co., Germany).

The spinning liquid was stored in a spinning liquid main tank 1, quantitatively metered by a metering pump 2, and then fed to a spinning liquid dropping device 3 to discontinuously change the flow of the spinning liquid.

Continually, the spinning liquid was fed to a bottom-up electrospinning devices with a 35 kV voltage applied thereto as shown in FIG. 4 having a nozzle block 4 with air feeding nozzles installed thereto, spun bottom-up onto fibers through nozzles, and coated on a paper/polypropylene nonwoven fabric passing over a collector 7 located on the top part at a velocity of 90 m/min.

The weight of the paper/polypropylene, nonwoven fabric was 157 g/m² and the width thereof was 120 cm.

At this time, in order to perform electrospinning, the nozzles 5 arranged on the nozzle block 4 were diagonally arranged, the number of nozzles was 9,720, the total number of nozzles was 38,880 since four nozzle blocks were used, the spinning distance was 15 cm, the throughput per hole was 1.2 mg/min, the reciprocating motion of the nozzle block 4 was performed at 2 m/min, an electric heater was installed on the collector 7, and the surface temperature of the collector was 35° C.

The spinning liquid flowing over the uppermost part of the nozzle block 4 during the spinning was forcedly carried to the spinning liquid main tank 1 by the use of a spinning liquid discharge device 12 using a suction air.

As the nozzles, used were nozzles having a nozzle outlet angle θ of 120°, an inner diameter Di of 0.9 mm and an outer diameter of 1 mm.

As the air feeding nozzles, used were air feeding nozzles having an inner diameter of 20 mm and an outer diameter of 23 mm and a distance h of 8 mm from the upper tips of the nozzles 5 to the upper tips of the air feeding nozzles 4b. The air velocity was 10 m/sec.

As a voltage generator, Model CH 50 of Simco Company was used.

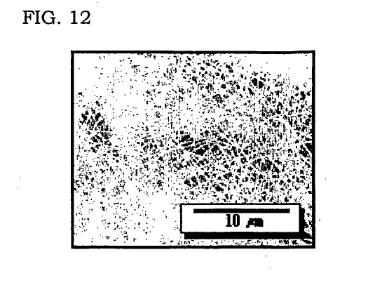

The result of photographing the paper/polypropylene nonwoven fabric by an electron microscope before coating nanofibers is as shown in FIG. 11, and the result of photographing the nonwoven fabric coated with nanofibers by an electron microscope is as shown in FIG. 12.

The result of measuring the pressure loss of the nonwoven fabric before coating nanofibers and the pressure loss of the nonwoven fabric coated with nanofibers by the method to be stated below is as shown in Table 1.

### COMPARATIVE EXAMPLE 1

A paper/polypropylene nonwoven fabric coated with nanofibers was produced in the same process and condition as Example 1 except that a conventional bottom-up electrospinning devices with no air feeding nozzle installed to a nozzle block 4 was used.

The result of measuring the pressure loss of the nonwoven fabric before coating nanofibers and the pressure loss of the nonwoven fabric coated with nanofibers by the method to be stated below is as shown in Table 1.

TABLE 1
Result of Measuring Pressure Loss

| | Pressure loss (mm H₂O) | Pressure loss (mm H₂O) |
|---|---|---|
| classification | before coating nanofibers | after coating nanofibers |
| Example 1 | 22 ± 5.0 | 41 ± 1.5 |
| Example 2 | 22 ± 5.0 | 41 ± 5.0 |

The pressure loss stated in Table 1 was measured according to the DIN 53,887 standard by using Textest FX 3300 air permeability tester.

### EXAMPLE 2

Chips of nylon 6 having a relative viscosity of 3.2 (determined in a 96% sulfuric acid solution) were dissolved in formic acid to prepare a 25% spinning liquid. The spinning liquid had a viscosity of 1200 centipoises (cPs) measured by using Rheometer-DV, III, Brookfield Colo., USA, an electric conductivity of 350 mS/m measured by a conductivity meter, CM-40G, TOA electronics Co., Japan, and a surface tension of 58 mN/m measured by a tension meter (K10St, Kruss Co., Germany).

The spinning liquid was stored in a main tank 1, quantitatively metered by a metering pump 2, and then fed to a spinning liquid dropping device 3 to discontinuously change the flow of the spinning liquid.

Continually the spinning liquid was fed to an bottom-up electrospinning devices with a 35 kV voltage applied thereto as shown in FIG. 4 having a nozzle block 4 with air feeding nozzles installed thereto, and spun bottom-up onto fibers through nozzles, to thus collect nanofibers on a polypropylene film coated with a silicon release agent passing over a collector 7.

At this time, the traveling speed of the polypropylene film was 4 m/min and the width thereof was 120 cm.

At this time, in order to perform electrospinning, the nozzles 5 arranged on the nozzle block 4 were diagonally arranged, the number of nozzles was 9,720 holes, the total number of nozzles was 38,880 since four nozzle blocks were used, the spinning distance was 15 cm, the throughput per one hole was 1.2 mg/min, the reciprocating motion of the nozzle block 4 was performed at 2 m/min, an electric heater was installed on the collector 7, and the surface temperature of the collector was 35° C.

The spinning liquid flowing over the uppermost part of the nozzle block 4 during the spinning was forcedly carried to the spinning liquid main tank 1 by the use of a spinning liquid discharge device 12 using a suction air.

The production velocity of the web was 4 m/min.

As the nozzles, used were nozzles having: a nozzle outlet angle θ of 120°, an inner diameter Di of 0.9 mm and an outer diameter of 1 mm.

As the air feeding nozzles, used were air feeding nozzles having an inner diameter of 20 mm and an outer diameter of 23 mm and a distance h of 10 mm from the upper tips of the nozzles 5 to the upper tips of the air feeding nozzles 4b. The air velocity was 8 m/sec.

As a voltage generator, Model CH 50 of Simco Company was used.

As a result of randomly picking 50 round samples having a 4 cm diameter from the produced nonwoven fabric and measuring their weight by a scale capable of measuring down to five places of decimals, the weight of the samples per unit area was 0.0122±3.7×10⁻⁴ g/cm².

### COMPARATIVE EXAMPLE 2

A nanofiber nonwoven fabric was produced in the same process and condition as Example 2 except that a conventional bottom-up electrospinning devices with no air feeding nozzle installed to a nozzle block 4 was used.

The weight of the samples per unit area measured in the same method as Example 2 was 0.0122±1.4×10⁻³ g/cm².

What is claimed is:

1. A bottom-up electrospinning devices, comprising: a spinning liquid main tank 1; a metering pump 2; a nozzle block 4; nozzles 5 installed on the nozzle block; a collector 7 for collecting fibers being spun from the nozzle block; and a voltage generator 9 for applying a voltage to the nozzle block 4 and the collector 7,
wherein: [I] the outlets of nozzles 5 installed on a nozzle block 4 are formed in an upper direction; [II] a collector 7 is located on the top part of the nozzle block 4; and [III] overflow removing nozzles 4a and air feeding nozzles 4b are sequentially installed around the outlets of the nozzles 5.

2. The devices of claim 1, wherein a spinning liquid dropping device 3 is installed between the spinning liquid main tank 1 and the nozzle block 4.

3. The devices of claim 1, wherein the nozzle block 4 is bilaterally reciprocated as a whole.

4. The devices of claim 1, wherein a heating device is installed in the collector 7.

5. The devices of claim 1, wherein a stirrer 11c is installed in the nozzle block 4.

6. The devices of claim 1, wherein a spinning liquid discharge device 12 forcedly feeding the liquid not spun in the nozzle regions to the spinning liquid main tank 1 is formed on the upper end of the nozzle block 4.

7. The devices of claim 1, wherein the collector 7 is fixed or continuously rotates.

8. The devices of claim 1, wherein the nozzles 5 located on the nozzle block 4 are arranged on a diagonal line or a straight line.

9. The devices of claim 1, wherein the outlets of the nozzles 5 are formed in more than one horn having an angle θ of 90 to 175°.

10. The devices of claim 1, wherein the nozzle block 4 comprises: [I] a nozzle plate 4f with nozzles 5 arranged thereon and a spinning liquid feed plate 4h located on the lower end of the nozzle plate and for feeding a spinning liquid to the nozzles; [II] overflow removing nozzles 4a surrounding the nozzles 5, an overflowing liquid temporary storage plate 4g connected to the overflow removing nozzles and located right below the nozzle plate and overflow removing nozzle supporting plate 4e located right above the overflowing liquid temporary storage plate and supporting the overflow removing nozzles; [III] air feeding nozzles 4b surrounding the nozzles 5 and the overflow removing nozzles 4a, an air feeding nozzle supporting plate 4c located on the uppermost end of the nozzle block and for supporting the air feeding nozzles and an air storage plate 4d located right below the air feeding nozzle supporting plate and for feeding air to the air feeding nozzles; [IV] a conductive plate 4i having pins arranged thereon in the same way as the nozzles are and located below the nozzle plate; and [V] a heating plate 4j located right below the spinning liquid feed plate.

11. Nanofibers produced by the bottom-up electrospinning devices of claim 1.

12. A method for coating nanofibers, wherein a nanofiber is continuously or discontinuously coated on a coating material by the bottom-up electrospinning devices of claim 1.

13. The method of claim 12, wherein the coating material includes a nonwoven fabric, a woven fabric, a knitted fabric, a film or a membrane film.

14. The method of claim 12, wherein nanofibers are coated in a multilayer by electrospinning more than two kinds of spinning liquids on the coating material, respectively, by respective bottom-up electrospinning devices.

15. A method for producing a hybrid type nanofiber web by consecutively arranging more than two bottom-up electrospinning devices of claim 1 and then electrospinning more than two kinds of spinning liquids sequentially on the collector 7 by the respective electrospinning devices.

16. A method for producing a hybrid type nanofiber web by stacking more than two kinds of nanofiber webs electrospun respectively by the bottom-up electrospinning devices of claim 1.
